(19) United States
(12) Patent Application Publication
(10) Pub. No.: US 2026/0322067 A1
(43) Pub. Date: Oct. 15, 2026

(54) METHOD FOR MANUFACTURING A RARE EARTH DOPED WAVEGUIDE, AND A RARE EARTH DOPED WAVEGUIDE

(71) Applicant: Aluvia Photonics B.V., Enschede (NL)

(72) Inventors: Ward Arnoldus Petrus Marinus Hendriks, Enschede (NL); Sonia Maria Garcia Blanco, Enschede (NL); Carlos Eduardo OSORNIO MARTINEZ, Enschede (NL); Dawson Benson BONNEVILLE, Enschede (NL); Kai Wang, Enschede (NL)

(21) Appl. No.: 19/482,710

(22) PCT Filed: Apr. 8, 2024
(86) PCT No.: PCT/NL2024/050181

§ 371 Date: Nov. 7, 2025

(30) Foreign Application Priority Data
May 8, 2023 (NL) 2034783

(51) Int. Cl. H01S 3/16; G02B 6/132; H01S 3/063; H01S 3/17

(52) U.S. Cl. CPC H01S 3/1608; G02B 6/132; H01S 3/0637; H01S 3/1616; H01S 3/1618; H01S 3/17

(57) ABSTRACT

The present application concerns a method for manufacturing an aluminium oxide optical waveguide doped with rare earth ions. The present application further concerns an aluminium oxide optical waveguide doped with rare earth ions that are preferably manufactured by said method. According to the present invention, the method comprises providing a substrate, depositing an aluminium oxide waveguide core layer doped with ions of a rare earth metal onto the substrate, and arranging a cladding layer on the deposited waveguide core, said arranging comprising at least one processing step during which the deposited waveguide core is subjected to a given maximum temperature. The method is characterized in that depositing the waveguide core comprises forming nano-crystallites in the waveguide core. A lowest temperature at which a quenching percentage of the deposited waveguide core significantly increases, exceeds the given maximum temperature, wherein the given maximum temperature is about 400 degrees Celsius or higher.

### CROSS REFERENCE TO RELATED APPLICATION

The present application is a U.S. National Phase of International Application No. PCT/NL2024/050181 entitled “METHOD FOR MANUFACTURING A RARE EARTH DOPED OPTICAL WAVEGUIDE, AND A RARE EARTH DOPED OPTICAL WAVEGUIDE”, and filed on Apr. 8, 2024. International Application No. PCT/NL2024/050181 claims priority to Netherlands Patent Application No. 2034783 filed on May 8, 2023. The entire contents of each of the above-listed applications are hereby incorporated by reference for all purposes.

### TECHNICAL FIELD

The present application concerns a method for manufacturing an aluminium oxide optical waveguide doped with rare earth ions. The present application further concerns an aluminium oxide optical waveguide doped with rare earth ions that are preferably manufactured by said method.

### BACKGROUND AND SUMMARY

Integrated photonics has become ubiquitous as its development opens opportunities for improved capabilities in applications over well-developed microelectronic technologies. Especially, as ultra-low loss waveguides are realized, a myriad of applications for photonics integrated circuits can be explored, among others, quantum computing, microwave photonics, biosensing, and non-linear sources. Rare earth doped media in particular is emerging as a competitive light source platform for a wide variety of applications, ranging from telecommunications, light detection and ranging, LIDAR, and environmental and biological sensing.

Known from the art is that an optical waveguide may be manufactured by providing a substrate, depositing an aluminium oxide waveguide core doped with ions of a rare earth metal on the substrate, and arranging a cladding layer on the deposited aluminium oxide waveguide core. Here, it is noted that arranging the cladding layer comprises at least one processing step during which the deposited aluminium oxide waveguide core is subjected to a given maximum temperature. Such optical waveguides may, for example, be used as parts of optical amplifiers.

An optical signal comprises anywhere between one, a few, or a continuous stream of signal photons of a particular wavelength. Optical amplifiers can amplify such a signal by providing an environment in which these signal photons can cause stimulated emission, stimulated emission being the process in which a signal photon interacts with an excited ion causing said ion to emit an identical photon and to return to a relaxed state. Specifically, such an environment may be provided by doping a medium such as a fibre or a waveguide with rare earth ions, i.e. ions of rare earth metals, and introducing pump energy into the medium to excite the rare earth ions. This pump energy can be provided with a pump laser, but alternatives are also known.

The skilled person is aware that the desired process of stimulated emission has less than desirable counterparts in energy migration and energy transfer up conversion. In energy migration, a signal photon, being either an original photon or a photon resulting from stimulated emission, is absorbed by a ‘relaxed’ rare earth ion, thereby exciting it. In energy transfer up conversion, a signal photon, being either an original photon or a photon resulting from stimulated emission, is absorbed by an already excited rare earth ion, exciting it even further. These processes are together sometimes referred to as quenching. How much quenching occurs can be expressed using any one of a number of characteristics, including the quenching percentage, the quenching factor, or the quenching rate.

In the present application, reference will be made to the quenching percentage.

Known from the art are optical waveguides with rare earth doped waveguide cores. Of the materials investigated for integrated photonics, aluminium oxide, Al₂O₃, has emerged as a promising platform material due to its large transparency window, low propagation losses, and high rare-earth solubility. Specifically, known in the art are optical waveguides that comprise a waveguide core made of amorphous aluminium oxide. These tend to show high optical performance and/or low losses in themselves. However, if, after deposition, the doped waveguide core is exposed to high temperatures, the quenching percentage significantly increases, making them less than ideal candidates for use in optical amplifiers.

The skilled person will be aware that optical losses in an optical waveguide are determined, not just by losses in the waveguide core, but also by losses in the cladding layer.

Optical losses in cladding layers may vary between different materials. For example, tetraethyl orthosilicate, TEOS, is known to display relatively low optical losses. However, for the manufacturing of a TEOS cladding layer, a high temperature annealing step is typically required. When combining the TEOS cladding layer with an amorphous aluminium oxide waveguide core doped with ions of a rare earth metal, a problem therefore arises in that the benefit of the optical quality of the TEOS cladding layer is mitigated by the significant increase of the quenching percentage of the amorphous aluminium oxide waveguide core due to the high temperatures involved when using a TEOS cladding layer on the amorphous aluminium oxide waveguide core.

There may also be other types of cladding layers that, to be arranged on the deposited aluminium oxide waveguide core, require processing steps during which said aluminium oxide waveguide core is subjected to high temperatures, resulting in the aforementioned increase in quenching percentage of the aluminium oxide waveguide cores. Hereinafter, cladding layers that require a high-temperature step performed at 400 degrees Celsius or higher during or after deposition are referred to as high-temperature cladding layers.

Accordingly, a problem exists when combining a known aluminium oxide waveguide core doped with ions of a rare earth metal with a high-temperature cladding layer. This problem prevents further reductions in optical losses for aluminium oxide waveguide cores. Consequently, high-temperature cladding layers cannot be combined with known amorphous aluminium oxide waveguide cores doped with ions of a rare earth metal, even though both components by themselves show high optical performance and/or low losses, and thus seem to be advantageous to use in combination.

This problem, for example, occurs in the paper “Characteristics of Er-doped Al₂O₃ thin films deposited by reactive co-sputtering” by MUSA, S., et al, IEEE journal of quantum electronics, 2000, 36.9:1089-1097. This paper discusses Er-doped Al₂O₃ thin films that have been deposited by reactive co-sputtering onto thermally oxidized Si-wafers. The thin films are deposited at a substrate temperature of 400° C. to ensure that they are amorphous and the waveguides have not been annealed. A relatively broad luminescence band, having an FWHM of 55 nm around the 1533 nm wavelength, has been measured. From gain versus pumping power curves, an up-conversion coefficient lower than 20×10⁻²⁵ m³/s has been derived.

The authors indicate that high temperature annealing results in clustering in ion implanted materials, leading to higher energy migration in the centre of the waveguide core. Consequently, the authors limit themselves to low-temperature reactive co-sputtering to produce Er:Al₂O₃ thin-films to avoid clustering of Er-ions.

Also known in the art are optical waveguides comprising a waveguide core that is manufactured as a single crystal. These show lower quenching percentages but are significantly more expensive and difficult to manufacture, meaning they are not easily commercialised.

An object of the present invention is to provide a method for manufacturing an optical waveguide comprising an aluminium oxide waveguide core and cladding layer in which at least one of the abovementioned problems is at least partially solved.

According to the present invention, this object is achieved with a method as described herein, which is characterized in that depositing the aluminium oxide waveguide core comprises forming nano-crystallites in the aluminium oxide waveguide core, wherein a lowest temperature at which a quenching percentage of the deposited waveguide core significantly increases exceeds the given maximum temperature, and wherein the given maximum temperature is about 400 degrees Celsius or higher.

The applicant has found that by deliberately allowing nano-crystallites to form during deposition, an aluminium oxide waveguide core can be manufactured that displays a lower quenching percentage than one made of amorphous material, while also being able to maintain said quenching percentage up to higher temperatures during subsequent processing steps.

When depositing at relatively low temperatures, no significant crystallization occurs, an amorphous layer doped with rare earth ions will be achieved, and some amount of ion clusters is formed. However, when such an amorphous aluminium oxide layer is subsequently subjected to a high temperature, e.g. 400 degrees Celsius and up, significantly more clustering will occur. In the amorphous material, rare earth ions can migrate towards each other, significantly increasing the quenching percentage.

When depositing at relatively high temperatures, crystallization will occur to such an extent that almost the entire deposited layer is filled with nano-crystallites.

Without being bound by theory, the Applicant notes that the energy required for rare earth ions in the abovementioned aluminium oxide layer with a large amount of relatively small crystallites to migrate and cluster is too high to be reached during the processing steps required to arrange a cladding layer.

That such a waveguide core is achieved can be confirmed by subjecting it to the given maximum temperature. No significant increase in the quenching percentage will occur, as very little clustering will occur inside the layer.

By deliberately allowing nano-crystallites to form, no to little amorphous material is present. This means the rare earth ions are far less mobile and are therefore less likely to cluster. The applicant has thereby overcome the technical prejudice that aluminium oxide waveguide cores doped with rare earth ions have to be made of amorphous aluminium oxide and/or that such a core cannot be annealed.

The Applicant found that by forming the nano-crystallites such that the given maximum temperature lies in a range between about 400 and about 1400 degrees Celsius, advantageous quenching percentage of the optical waveguide can be obtained. A maximum temperature that is lower than 400 degrees Celsius would indicate that a relatively large amount of amorphous aluminium oxide would be available after deposition of the waveguide core, resulting in a relatively high mobility for the rare earth ions when arranging the cladding layer. On the other hand, a maximum temperature that is higher than 1400 degrees Celsius would risk deterioration of the aluminium oxide waveguide core. The skilled person will appreciate that around 1400 degrees Celsius the glass transition temperature of aluminium oxide starts, so subjecting the aluminium oxide waveguide core to this temperature may cause reflow of the structure.

It is noted that the given maximum temperature preferably lies in a range between about 400 and about 1400, preferably between about 500 and about 800 degrees Celsius and is more preferably about 550 degrees Celsius.

In the context of the present application, an increase in quenching percentage may be considered significant when about 20% points or more, preferably when between about 5% to about 20%.

Depending on the particular cladding layer that is used, arranging the cladding layer may comprise depositing the cladding layer on the deposited waveguide core. The at least one processing step during which the given maximum temperature is achieved comprises annealing the combination of the substrate, deposited waveguide core, and deposited cladding layer at said given maximum temperature. In such embodiments, the quenching percentage of the aluminium oxide waveguide core after said deposition of the cladding layer and before said annealing may be between about 5% and about 35%. Additionally or alternatively, the quenching percentage of the waveguide core after said annealing is between about 0% and about 35%, preferably between about 0% and about 5%.

For some cladding layers, the at least one processing step comprises depositing the cladding layer on the aluminium oxide waveguide core at said given maximum temperature. In such embodiments, the quenching percentage of the aluminium oxide waveguide core after said deposition of the cladding layer may be between about 0% and about 35%, preferably between about 0% and about 5%.

Various materials may be used as specific implementations for the rare earth ions. The rare earth metal may be a lanthanide, such as Erbium (Er³⁺), Ytterbium (Yb³⁺), Thulium (Tm³⁺) and/or Neodymium (Nd³⁺).

In a preferred embodiment, the aluminium oxide is stoichiometric. The skilled person will appreciate that this depends on the practical implementation and that this cannot always be achieved. Hence, for some embodiments, it can be said that the waveguide core comprises AlₓO_{y}, wherein 1.5<x<2.5 and 2.5<y<3.5, such as x=1.6, and y=3.4, and preferably x=2, and y=3.

The skilled person will appreciate that the waveguide core can be grown using various methods, such as any one of reactive sputter deposition, atomic layer deposition, evaporation, or pulsed laser deposition.

Various types of cladding layers may also be used, such as a TEOS layer, a Silicon oxynitride layer, or a polymer layer. Depending on the desired cladding layer, one of a number of application methods may be used. That is, the cladding layer may be arranged using any one of plasma enhanced vapor deposition, low pressure chemical vapor deposition, evaporation, sputtering, or atomic layer deposition.

Various types of substrates may also be used, such as a silicon substrate, a silicon thermal oxide substrate, or a quartz substrate.

The optical waveguide can also take on any one of a number of forms, such as a slab waveguide or a channel waveguide.

In some embodiments, losses in the manufactured waveguide may be reduced further by including in the manufacturing method, between depositing the aluminium oxide waveguide core and arranging the cladding layer, the steps of reducing surface roughness of the aluminium oxide waveguide core, for example using chemical mechanical polishing.

In some embodiments, the method further comprises defining a shape and/or size of the aluminium oxide waveguide core using, for example, at least one of lithography and etching, before arranging the cladding layer.

The skilled person will appreciate that the exact settings necessary to manufacture an optical waveguide will always also depend on the particular machine used, the batch of resources/material used, etc. To figure out the exact settings ideal for providing an optical waveguide according the invention, in some embodiments the method further comprises:
at a deposition rate for aluminium oxide, depositing aluminium oxide layers doped with rare earth ions at varying substrate temperatures and/or at varying substrate bias voltages on respective substrates;
for each deposited aluminium oxide layer, measuring its quenching percentage;
selecting, as optimal settings, said deposition rate and the substrate temperature and substrate bias voltage with which the aluminium oxide layer was manufactured that had the lowest quenching percentage; and
using the optimal settings when depositing the aluminium oxide waveguide core for manufacturing an optical waveguide.

According to a further aspect of the application, an optical waveguide core is provided that comprises a substrate, an aluminium oxide waveguide core and a cladding layer. The aluminium oxide waveguide core is doped with ions of a rare earth metal and is arranged on the substrate. The cladding layer is arranged on the waveguide core. The aluminium oxide waveguide core comprises nano-crystallites and has a quenching percentage of the optical waveguide is 5% or less. The cladding layer comprises a high-temperature cladding layer.

The morphology of the waveguide core as a whole can be considered nano-crystalline or polycrystalline depending on the size of the crystallites and how much of the waveguide core is in this form. In a particular embodiment, the nano-crystallites may be between about 1 nanometre and about 30 nanometre in size, preferably between about 1 nanometre and about 10 nanometre in size. In a particular embodiment, the nano-crystallites form at least 50% by weight of the aluminium oxide waveguide core, preferably at least 75%, and more preferably at least 99%.

Various cladding layers can be used. For example, the high-temperature cladding layer may comprises at least one a TEOS layer or a Silicon oxynitride layer.

The optical waveguide can take on any one of a number of forms, including a slab waveguide or a channel waveguide.

An optical waveguide as discussed in the above is preferably manufactured by one of the earlier mentioned method.

### BRIEF DESCRIPTION OF THE FIGURES

Next, the present invention will be described by referring to the appended drawings, wherein identical reference signs will be used to refer to the same or similar components, and wherein:

FIG. 1 shows a flowchart of a method for manufacturing an optical waveguide in accordance with the present invention;

FIG. 2 shows a cross-section of a slab waveguide in accordance with the present invention;

FIG. 3 shows a flowchart of a preferred embodiment of the method of FIG. 1;

FIG. 4 shows an example of a reactive co-sputtering system that may be configured to deposit an aluminium oxide waveguide core in accordance with the present invention;

FIG. 5 illustrates TEM pictures of deposited aluminium oxide waveguide cores for various substrate temperatures;

FIG. 6A and FIG. 6B illustrate AFM pictures of a deposited aluminium oxide waveguide cores for various substrate temperatures;

FIG. 7A and FIG. 7B shows a graph relating, on the X-axis, deposition temperatures for aluminium oxide waveguide cores, and, on the Y-axis, measured refractive index thereof, and a graph relating, for a number of deposition temperatures, on the X-axis, a wavelength of light propagated through aluminium oxide waveguide cores deposited at said temperatures, and, on the Y-axis, measured propagation losses therein.

FIG. 8A shows a graph relating, on the X-axis, the temperature at which a waveguide core is deposited, to, on the Y-axis, the size of crystallites formed in said aluminium oxide waveguide core;

FIG. 8B shows a graph relating, on the X-axis, the temperature at which a waveguide core is deposited, to, on the Y-axis, the percentage by weight of the waveguide core that is in a particular phase, specifically amorphous (A) or crystalline (C);

FIG. 8C shows a graph relating, on the X-axis, the temperature at which a waveguide core is deposited, to, on the Y-axis, optical losses achieved in said waveguide core;

FIGS. 9A and 9B both show graphs relating, on the X-axis, the distance over which light propagated through a waveguide core, to, on the Y-axis, intensity of said light.

FIG. 10 shows a testing set up for measuring the gain in an optical waveguide.

FIG. 11 shows spirals of different lengths for testing amplification characteristics.

### DETAILED DESCRIPTION

In the context of this application, the metric used to describe the amount of quenching that occurs in an optical waveguide—or, more specifically, would occur if said waveguide would be used for optical amplification and/or would be included in an optical amplifier—is the quenching percentage. The skilled person will be aware that this can be derived in a number of ways.

Regardless, according to one definition adhered to within the context of the present invention, the quenching percentage may refer to the percentage of rare earth ions that is not accessible by the signal photons. This may be because the decay-rate constant is too fast.

This percentage may be derived by causing steady state excitation in the doped waveguide core, i.e. providing pump energy to the waveguide core until it is saturated, and, after having stopped providing said pump energy, measure the non-radioactive decay. Depending on an assumed distribution of excited states, an assumption that the skilled person is aware of and that depends on the rare earth ion in question, and the measured total non-radioactive decay, it is possible to derive what percentage or fraction of the rare earth ions is quenched and which is not.

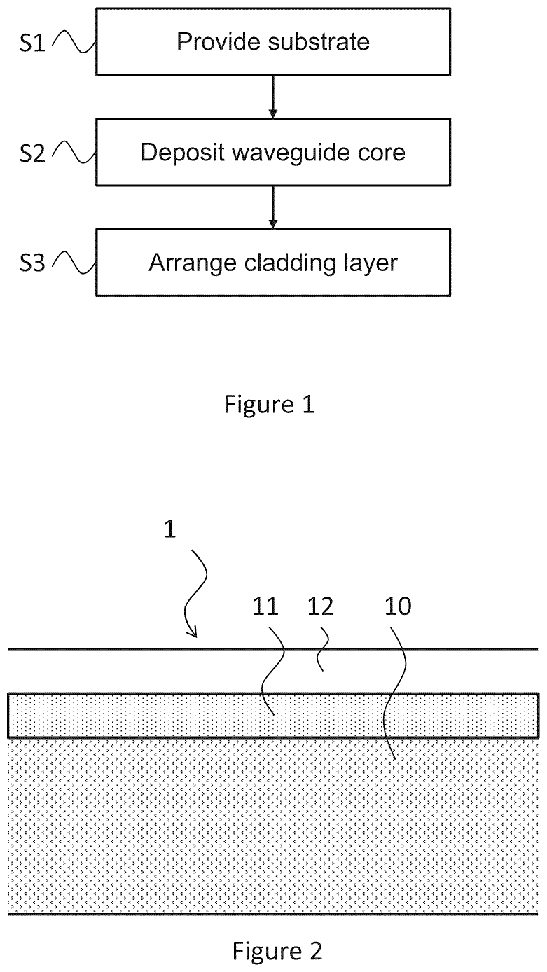

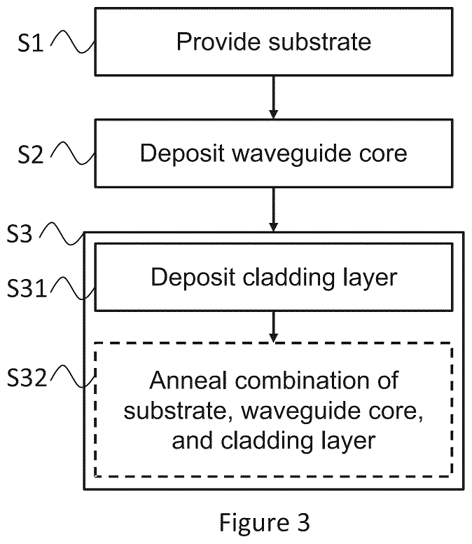

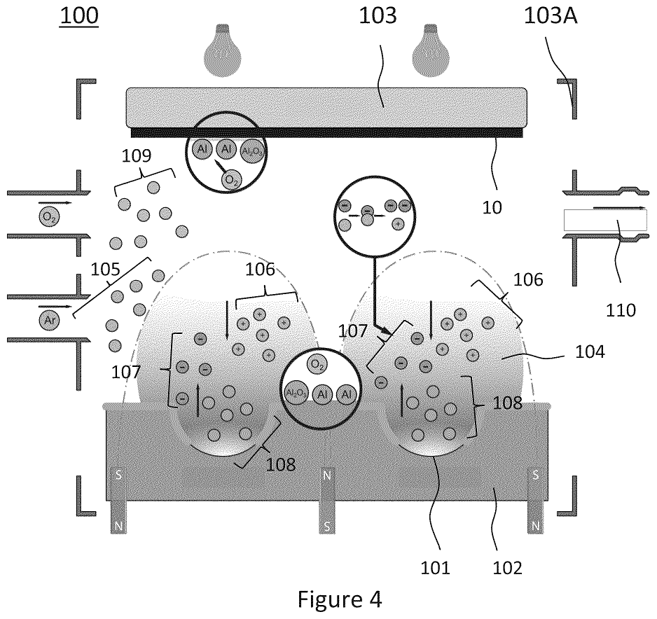

FIG. 1 shows a flowchart including steps S1-S3 of one embodiment of a method for manufacturing an optical waveguide according to the present invention. FIG. 2 shows a schematic cross-section of an optical waveguide, as, for example, can be manufactured with the method according to the invention. FIG. 3 shows a flowchart of a preferred embodiment of said method.

In a step S1, a substrate 10 is provided. In a next step S2, an aluminium oxide waveguide core doped 11 with ions of a rare earth metal is deposited on the substrate. Specifically, aluminium oxide core 11 is deposited such that nano-crystallites are formed therein. In a next step S3, a cladding layer 12 is arranged on aluminium oxide waveguide core 11. During at least one processing step required to arrange cladding layer 12, aluminium oxide waveguide core 11 is subjected to a given maximum temperature, which is about 400 degrees Celsius or higher, and preferably between about 400 degrees and about 1400 degrees Celsius. The lowest temperature at which a quenching percentage of the deposited waveguide core significantly increases, exceeds the given maximum temperature.

Increasing the maximum temperature beyond about 1400 degrees Celsius risks deterioration of aluminium oxide waveguide core 11. The skilled person will appreciate that around 1400 degrees Celsius the glass transition temperature of aluminium oxide starts, so subjecting the waveguide core to this temperature may cause reflow of the structure. Moreover, such a maximum temperature may also deteriorate the performance of the other components of the waveguide, depending on the materials used. Substrate 10 may be made of silicon, which may start to melt around 1400 degrees Celsius. Substrate 10 may also comprise silicon dioxide, in which, when exposed to such temperatures, local density fluctuations may form that cause scattering and thus degrade performance.

In a particular embodiment, the substrate is made of thermal SiO2 and is about 6.0 μm thick, the waveguide core is made of Al₂O₃:Er³⁺ and is about 1.6 μm wide and 0.78 μm thick, and the cladding layer is made of CVD SiO2 and is about 8.0 μm thick.

The applicant finds that, apart from the abovementioned aluminium oxide, other host materials that allow for formation of nano-crystallites and which have sufficiently high rare earth solubility can be used. One such alternative host material is aluminium nitride. The skilled person will be aware of how the following specification of a manufacturing process for an aluminium oxide waveguide core, can and/or should be adapted for manufacturing other host materials, such as an aluminium nitride waveguide core.

Other rare earth metals may also be used. The ions may for example be lanthanides. Some specific examples are Erbium (Er³⁺), Ytterbium (Yb³⁺), Thulium (Tm³⁺) and/or Neodymium (Nd³⁺). The skilled person will be aware of how the following specification of a manufacturing process for an Erbium, can and/or should be adapted for manufacturing a waveguide core doped with other rare earth ions.

The concentration of rare earth ions may be anywhere between about 0.25×10²⁰ ions/cm³ and about 1×10²¹ ions/cm³, preferably between about 0.25×10²⁰ ions/cm³ and about 4×10²⁰ ions/cm³.

The method according to the invention ensures that clusters do not form or that at least very few clusters form. A corresponding positive formulation thereto is that the method according to the invention provides a waveguide core throughout which the rare earth metal ions are evenly and/or uniformly distributed. The skilled person will appreciate that the positioning of the rare earth ions is, however, never exactly even or uniform. However, that is also not necessary. In the context of this application, evenly distributed or uniformly distributed should be understood as that, when the distribution of the ions throughout the waveguide core is described as a stochastic process, said process would show an approximately uniform distribution.

Now referring to FIG. 3, step S3 of arranging the cladding layer may comprise a step S31 of depositing a cladding layer 12 on aluminium oxide waveguide core 11. Step 31 may be the processing step during which aluminium oxide waveguide core 11 is subjected to the given maximum temperature. This may for example apply in embodiments where a polymer-based cladding layer is deposited.

Alternatively, a high-temperature step is not part of the deposition of the cladding layer but part of a subsequent heating step. In FIG. 3, an example of such subsequent step is provided as step S32 in which the combination of substrate 10, deposited aluminium oxide waveguide core 11, and arranged cladding 12 layer is annealed thereby subjecting aluminium oxide waveguide core 11 to the given maximum temperature. This applies for example in embodiments where a TEOS cladding layer is deposited.

It should be noted that various other steps can be performed in between the deposition of aluminium oxide waveguide core 11 and the arrangement of cladding layer 12. For example, the deposited aluminium oxide layer can be subjected to chemical mechanical polishing to reduce surface roughness and to e-beam lithography and reactive etching steps to define a channel waveguide or other type of waveguide.

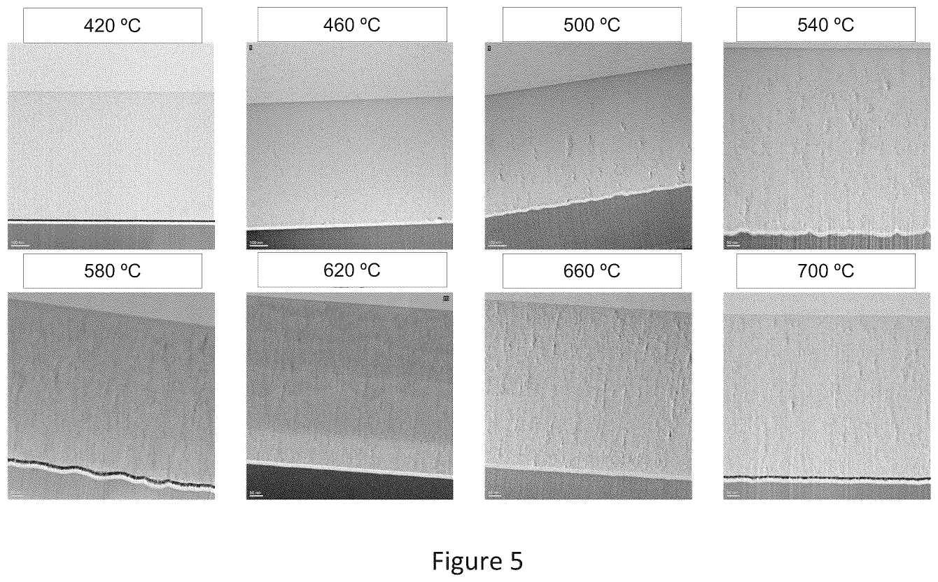

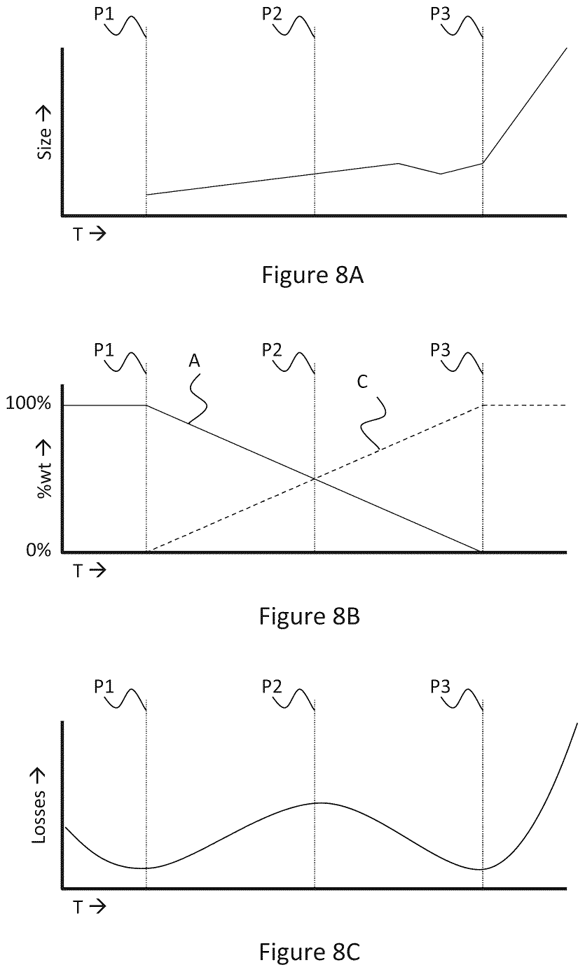

A first possible implementation for depositing the aluminium oxide waveguide core 11 such that nano-crystallites are formed is discussed below, referring to FIGS. 4 to 7. A conceptual explanation of the nano-crystallites formed is given in relation to FIGS. 8A-C.

The Al₂O₃:Er³⁺ thin films used in embodiments of the present invention can be deposited by reactive sputtering onto a silicon wafer having an 8 micrometres oxide buffer layer. The advantage of reactive sputtering exploited here is a result of the energy available per adatom on the substrate. The adatoms landing on the substrate have a high mobility, resulting in high-density layer morphologies available at relatively low substrate temperatures and high deposition rates. This allows for the deposition of high-density Al₂O₃:Er³⁺ layers at CMOS compatible wafer temperatures, with slab waveguide propagation losses below 0.1 dB/cm at 1550 nm.

While several methods for achieving Al₂O₃:Er³⁺ optical waveguides with low quenching have been discussed, no link with the morphology of the aluminium oxide has been demonstrated in the prior art. The applicant realized that, given the complexity of reproducing reactive sputter deposition processes, an understanding of the morphology of the aluminium oxide can facilitate improved reproducibility and layer quality.

The morphology of an Al₂O₃:Er³⁺ layer deposited by reactive sputtering is primarily determined by the available energy per adatom, EPA, and the material properties of the deposited layer. The material properties determining the morphology are the activation energy and diffusion constants that determine the diffusion length of the adatom at a given kinetic energy available per adatom, and the critical nucleation dimension that determines a critical diffusion length required for stable nucleation. While the material properties are a given for an Al₂O₃:Er³⁺ layer, the energy per adatom is a ratio of the deposition rate and the total energy contributions during deposition.

For reactive sputtering, the total energy flux is a linear combination of different contributions. The sputtering process contributions to the energy flux towards the substrate can be classified in at least four groups.

The contributions of the atoms and molecules adhering to the substrate required for Al₂O₃ layer formation should be considered first. Adatoms that have been accelerated from the target have contributed their kinetic energy as they were adsorbed on the substrate. In addition, when an oxygen molecule is adsorbed, its kinetic energy is also contributed. Even when atoms or molecules are not adsorbed, part of their kinetic energies can still be transferred when colliding with the substrate. Especially when the gas molecules get energized by collisions with higher velocity ions, this contribution can become significant. Another form of kinetic energy is related to the temperature of the substrate. Furthermore, besides the kinetic energy contributions to the layer formation, the potential energy released by the exothermic chemical reaction forming Al₂O₃:Er³⁺ is a significant contribution.

The three other groups of energy contributions are radiation from the plasma, electrons incident on the substrate, and ions accelerated towards the substrate. Note, that a substrate bias can be applied. Increasing and/or decreasing said bias can be done to increase or decrease the electron and ion bombardment on the substrate.

All the energy contributions add to the available energy per adatom and thus influence the layer morphology and consequent propagation losses.

In an embodiment, the Al₂O₃:Er³⁺ layer can be deposited using an AJA ATC 1500 RF reactive co-sputtering system 100 on 10 centimetre silicon wafers having an 8 micrometre thick thermal oxide buffer layer.

System 100, which is schematically illustrated in FIG. 4, comprises a target 101 comprising aluminium with a 99.9995% purity, which is arranged above cathode 102. System 100 further comprises a second target 101B (not shown) comprising the rare earth metal, e.g. erbium at 99.95% purity or ytterbium at 99.9%. The second target can be arranged on the same, or a separate cathode adjacent to cathode 102. Opposite to targets 101 and 101B, substrate 10 is arranged on anode 103, which is electrically connected to chamber 103A. RF power is applied between anode 103 and cathode 102. Two targets 101 and 101B can be powered with their own RF power source, thus having individual bias voltages. This causes the generation of a plasma 104 in which supplied Ar atoms 105 are ionized into Ar ions 106 and electrons 107. Ar ions 106 are accelerated towards target 101 under the influence of a self-generated DC bias. At target 101, they will collide with Al atoms thereby generating a stream of Al atoms 108 towards substrate 10. At substrate 10, Al atoms 108 that have deposited onto substrate 10 will react with oxygen molecules 109 to form aluminium oxide. At target 101B, the Ar ions 106 collide with Er atoms thereby generating a stream of Er atoms, specifically Er³⁺ ions, towards substrate 10.

The main deposition chamber is evacuated through inlet 110 to a base pressure of 0.1 microTorr to prevent incorporation of hydroxide ions in the Al₂O₃:Er³⁺ layer, which induce absorption losses around 750 nm, 970 nm, and 1400 nm.

For the magnetron discharge to be sustained, an equilibrium between the secondary electrons emission from target 101 under ion bombardment and the rate of electrons 107 escaping plasma 104 needs to be maintained. While an RF power source does not directly apply a DC potential difference between cathode 102 and anode 103, electrons 107 in plasma 104 absorb the RF energy much more efficiently than heavier argon ions 106. The high electron mobility causes electrons 107 to be collected on the electrodes. A self-generated DC bias voltage is then a consequence of the asymmetry between target 101 and chamber 103A of sputtering system 100.

A magnetic field is applied using permanent magnets below the targets to increase the electron density in plasma 104, thereby increasing the argon ionization rate and reducing the discharge voltage required. In addition, the magnetic field greatly increases the sputter yield by the increase of ionization and therefore bombardment rate of the target.

Sputtering system 100 further comprises heating means, such as infrared heaters 111, for heating substrate 10 either directly or via anode 103 on which substrate 10 is arranged.

Exemplary process conditions for depositing the aluminium oxide waveguide core are listed in the table below.

| Parameter | Value | Unit |
|---|---|---|
| Base pressure | <0.3 | μTorr |
| Argon flow | 30 | Sccm |
| Oxygen flow | 3.0 ± 0.2 | Sccm |
| Oxygen partial pressure | 0.2 ± 0.1 | mTorr |
| Pressure | 3.5 ± 0.1 | mTorr |
| Pump flow | 50 ± 2 | l/s |
| Substrate set temperature | 420 460 500 540 580 620 | ° C. |
| | 660 700 | |
| Target-substrate distance | 15.2 | cm |
| Power for target 101 | 200 | W |

Given the dependence of the layer morphology on available energy per adatom, it is possible to vary the substrate temperature for the purpose of varying the available energy per adatom as it is mostly independent of the other parameters in the process. This allows the investigation of layer morphology as it changes with substrate temperature and the corresponding optical propagation losses in the layers.

The substrate temperatures are set temperatures measured on the substrate holder and are therefore not the exact temperature of the substrate. A calibration of substrate temperature as a function of the set temperature can be provided.

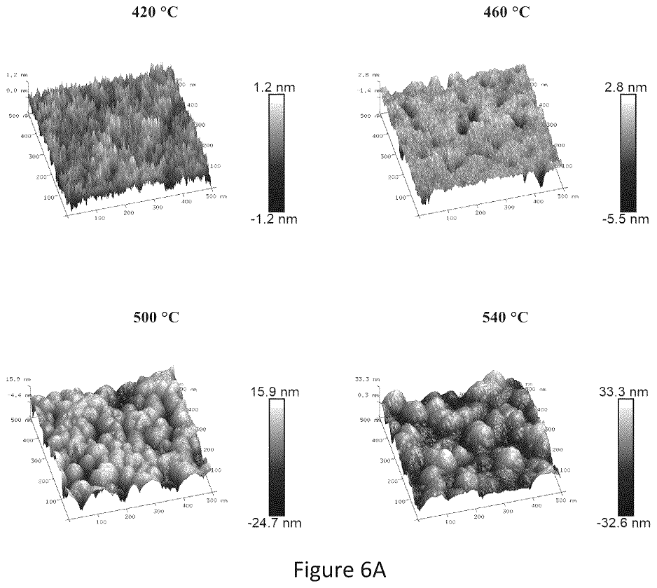

FIG. 5 illustrates TEM pictures of a deposited aluminium oxide waveguide layer for various substrate temperatures. The morphology of the layer at the lowest chosen temperature of 420 degrees Celsius is amorphous. As the substrate temperature is increased to 460 degrees Celsius nano-crystallites start to form, of which the density is significantly increased for 500 degrees Celsius and 540 degrees Celsius.

As the temperature is increased from 500 to 580 degrees Celsius, the surface roughness increases with ever larger waviness. While the waviness of the surface is still present for the layer deposited at 580 degrees Celsius, a clear transition from a mostly amorphous layer with nano-crystallites to a mostly polycrystalline morphology has occurred. The waviness disappears from a temperature of 620 degrees Celsius as an increasingly polycrystalline morphology is observed with a slight columnar growth profile. As the temperature is further increased to 700 degrees Celsius, no significant difference in the morphology is observed.

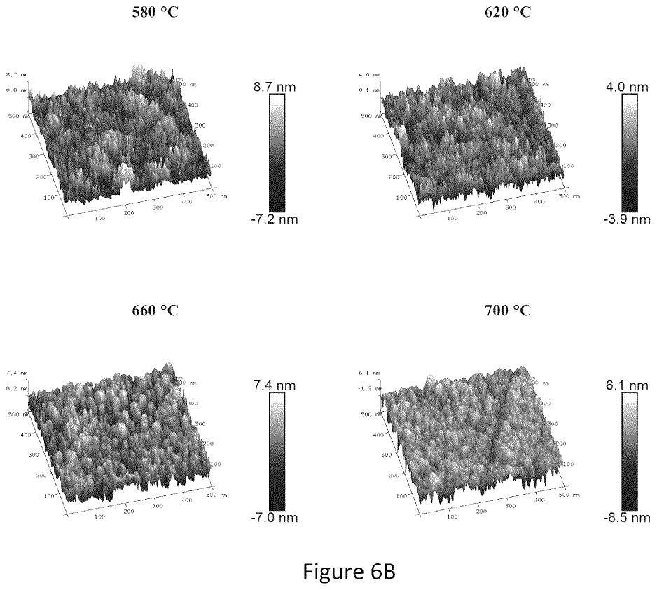

FIGS. 6A and 6B illustrate AFM measurements of a deposited aluminium oxide waveguide layer for various substrate temperatures. The AFM measurements show the waviness appearing at 500 degrees Celsius (FIG. 6A, bottom left), increasing in amplitude at 540 degrees Celsius (FIG. 6A, bottom right), and reducing and disappearing at 620 degrees Celsius (FIG. 6B, top right). In addition to the waviness, the layers grown at a temperature from 500 degrees Celsius (FIG. 6A, bottom left) to 580 degrees Celsius (FIG. 6B top left) exhibit a decreased refractive index and thickness uniformity.

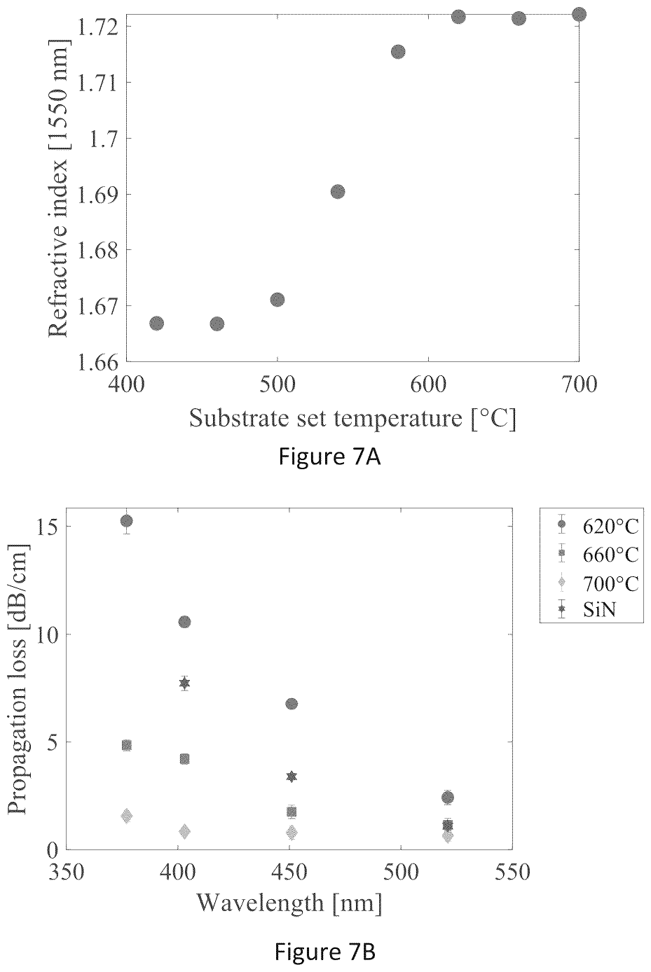

FIG. 7, bottom, specifically shows the refractive index of aluminium oxide layers measured by ellipsometry at 1550 nm, for varying deposition temperatures.

The optical propagation losses for each aluminium oxide layer have been investigated using a Metricon 2010/M41, with a fibre loss module. These losses are illustrated in figure, top. Clearly, losses decrease with increasing deposition temperature down to 1.57 dB/cm at 377 nm and 0.84 dB/cm at 403 nm for the layer grown at 700 degrees Celsius substrate temperature.

In alternative embodiments, when depositing an aluminium nitride waveguide core, the exact deposition temperatures may be different from those mentioned in relation to FIGS. 5 and 6, however the Applicant does find that the same behaviour occurs. The same changes in morphology, and/or the same trends in refractive index and thickness uniformity can be observed in aluminium nitride waveguide cores, when deposited at varying temperatures. The teachings derived from FIGS. 4-7, while explaining based on the aluminium oxide waveguide core embodiment, can also be applied to the aluminium nitride waveguide core embodiment.

FIGS. 8A-C each show a graph that relates the deposition temperature at which an aluminium oxide waveguide core 11 is deposited, to various properties of said core 11. On the X-axis of each of these graphs the deposition temperature is shown. The skilled person will appreciate that the exact temperature values at which a particular waveguide core is deposited is strongly machine dependent, e.g. the machine given value for the ‘deposition temperature’ can deviate from an actual, practically very hard to know, temperature of the waveguide core. However, given a particular machine and a deposition rate that can be achieved, a temperature sweep can be performed to determine exact temperature values at which the behaviour as elucidated in the graphs shown in FIGS. 8A-C occurs.

In the art, there is a clear preference for manufacturing amorphous Al₂O₃ waveguide cores to be doped with rare earth ions as these cores have displayed low optical losses. In FIGS. 8A-8C, the deposition temperature at which such waveguides are achieved is referred to as temperature P1. If, starting from P1, the deposition temperature is decreased, the deposited layer will become less dense and voids will be present in the amorphous aluminium oxide. Said voids may act as scattering objects and may cause losses. If, starting from P1, the deposition temperature is increased, nano-crystallites form in the amorphous material. Said nano-crystallites may act as scattering objects and may cause losses.

As shown in FIGS. 8A-8C, P1 is a local minimum at which a balance is struck between reducing the amount voids and preventing the formation of nano-crystallites. At P1, relatively low losses can be achieved. Known aluminium oxide optical waveguides are based on aluminium oxide layers deposited at temperatures corresponding to P1. However, such layers have the aforementioned disadvantage of being vulnerable to high temperature processing steps that follow the deposition of the aluminium oxide layer.

The Applicant realised that in aluminium oxide optical waveguides deposited at deposition temperatures in a range around P1, the largest losses are caused by local differences in dielectric properties. Both voids and crystallites have different dielectric properties than amorphous aluminium oxide. More voids and/or more crystallites means such local differences occur more often and optical losses will increase.

The Applicant further realised that such local differences will most often occur, and therefore that the losses caused thereby may be at their highest, when the aluminium oxide layer comprises comparable amounts of amorphous material and nano crystallites. This may for example be seen in FIG. 8B, in which line A describes how much aluminium oxide in the layer, expressed in weight percentage, is in the amorphous phase, and line C describes how much aluminium oxide, expressed in weight percentage, is in the crystalline phase. The skilled person will appreciate that the amount of amorphous material and/or the number of nano-crystallites may also be expressed using other units and/or metrics.

The Applicant further realised that when the deposition temperature is increased, the nano-crystallites will at some temperature overtake the amorphous material as the dominant material in the deposited layer. As the number of discontinuities between amorphous and crystalline aluminium oxide decreases due to the decreasing amount of amorphous aluminium oxide, a reduction in optical losses can be observed beyond a temperature P2. In FIG. 8B, temperature P2 is chosen as the temperature at which the content of amorphous and crystalline aluminium oxide content is identical for illustrative purposes only.

The reduction in optical losses continues up to the deposition temperature at which substantially all aluminium oxide in the waveguide core takes the form of nano-crystallites and little to none of it is in the amorphous phase. This point may be referred to as P3. FIG. 8C further indicates a rectangle R that illustrates the temperature range corresponding to the temperature variation in FIG. 7, top.

Equivocally, for deposition temperatures between P2 and P3, it is the sporadic presence of volumes of amorphous material in between the otherwise nano-crystalline aluminium oxide that can be considered the cause of scattering. Hence, when further increasing the deposition temperature, less and/or smaller volumes of amorphous material are formed, local differences occur less often, and losses decrease.

The Applicant furthermore realised that, while in the range P1 and P3, more and more aluminium oxide takes on the shape of nano-crystallites, that a size of the individual nano-crystallites does not increase significantly. This is conceptually reflected in FIG. 8A. Only when deposition temperatures above P3 are used, there may be a significant increase in the size of the individual crystallites while the percentage of aluminium oxide included in crystallites in itself stays the same. It should be noted that no size is indicated for deposition temperatures below P1 as almost no nano-crystallites are present. Increasing the temperature beyond P3 will cause nano-crystallites to combine into large crystallites. These relatively large crystallites cause an increase in optical scattering, thereby increases the optical losses in the layer. As such, at temperature P3 a local minimum can be observed in the losses that is comparable to the minimum at temperature P1. However, unlike deposited aluminium oxide layers deposited at temperature P1, aluminium oxide layers deposited at temperature P3 are much less susceptible to subsequent heating steps, such as an annealing step for processing a deposited cladding layer.

The morphology achieved at deposition temperatures P3 may also be described as polycrystalline aluminium oxide, saturated with nano-crystallites. Here, nano-crystallites refer to crystallites with a size that is relatively small compared to the waveguide of the light that is to travel through the optical waveguide. This morphology is advantageous because:
a) nano-crystallites are so small that they do not cause significant Rayleigh scattering due to their size;
b) saturation of the core with nano-crystallites ensures little to no fluctuations in dielectric properties throughout the core thereby also limiting Rayleigh scattering;
c) saturation of the core with nano-crystallites also means that existing nano-crystallites have little to no amorphous material in their surroundings to absorb and grow with;
d) growth occurring due to nano-crystallites mutually aligning and forming a single larger crystallite only occurs at much higher temperatures.

Graphs in FIGS. 8A-C conceptually show when depositing an aluminium oxide layer at various substrate temperatures. While points P1, P2, and P3 are indicated in each graph, the behaviour related therein does not have to occur exactly at the same temperatures for each property described in FIGS. 8A-C. Also, while FIG. 8C suggests the local minima at P1 and P3 allow for achieving the same low losses, implementations of the method according to the invention may, for a plethora of reasons, result in local minima P1 and P3 achieving different levels of losses.

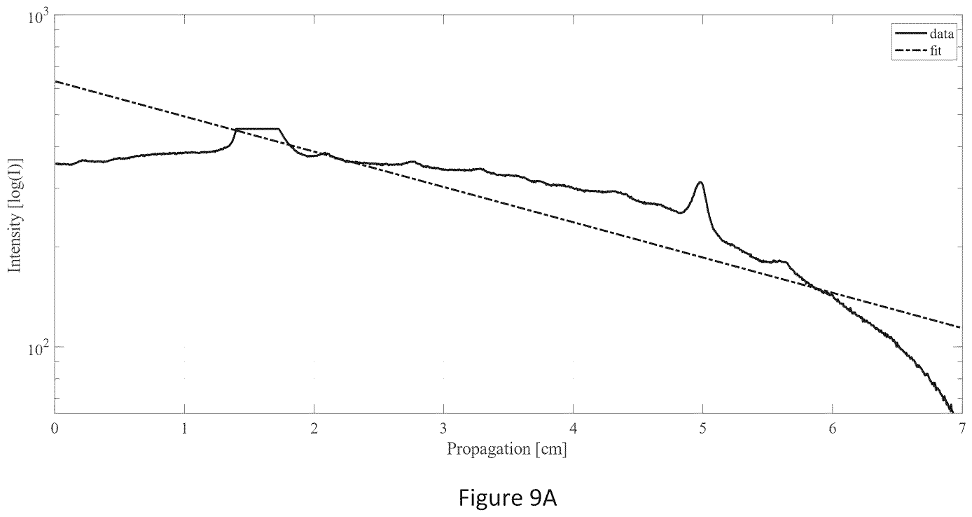

The Applicant finds that subjecting aluminium oxide waveguide core 11, in which nano-crystallites are formed, to temperatures of 550 or higher such as 800 degrees or higher may even be advantageous and/or decrease losses. The latter is for example shown in FIGS. 9A and 9B.

When aluminium oxide waveguide core 11 is exposed to such a temperature, while the growth of the nano-crystallites is very limited, said growth will still consume all or at least most of the amorphous aluminium oxide that may have formed during deposition of aluminium oxide waveguide core 11. After being subjected to said temperature, if less amorphous aluminium oxide is present, local differences in dielectric properties occur less often and thus scattering decreases.

The skilled person will appreciate that it can be confirmed that an aluminium oxide waveguide core with nano-crystallites is achieved by depositing said core without the rare earth ions and by subjecting it to a temperature of about 800 degrees or higher, preferably between about 800 and about 1400 degrees. No significant changes in the optical performance will occur, as very little crystal growth will occur inside the undoped layer. The mentioned increase in size of said crystallites may be considered significant when about 100% or more, preferably when between about 100% and about 50%. This has to be tested without the rare earth ions as these already cause degradation of the optical performance due to clustering in amorphous materials at temperatures lower than 800, such as 400 degrees.

For FIG. 9A, the aluminium oxide waveguide core in question is one deposited such that nano-crystallites are formed in the aluminium oxide. No further processing step was performed during which the deposited aluminium oxide waveguide core was subjected to a temperature of 800 degrees Celsius or more. The losses achieved are 1+/−0.5 dB/cm.

For FIG. 9B, the aluminium oxide waveguide core of FIG. 9A was subjected to about 1150 degrees Celsius for about four hours, in a nitrogen environment. The losses achieved are 0.7+/−0.2 dB/cm.

The intensity of light, as given on the Y-axis, is an estimate derived from scattering light measured over the propagation length of the waveguide core. Not willing to be bound by theory, the skilled person will appreciate that due to limitations of this estimate it may seem that the intensity of the light increases, while it is still safe to say that losses do occur. These losses are estimated by fitting the measurement data to a log-linear model using a maximum likelihood estimator sample consensus, MLESAC, algorithm. The given error margins are determined by fitting different sections of the total propagation. The skilled person will appreciate that other approaches to estimate the intensity of light inside the waveguide core, and derive average losses from that measurement data may also be used.

In alternative embodiments, when depositing an aluminium nitride waveguide core, the temperature values for P1, P2, or P3 may be different from those found for aluminium oxide waveguide cores, however the Applicant does find that the same behaviour occurs. Similar changes in the phase that the aluminium nitride has, e.g. amorph or (nano-)crystalline, similar increase in size of the (nano-)crystallites, and a conceptually comparable loss profile can be identified in aluminium nitride waveguide cores, when deposited at varying temperatures. The teachings explained in FIGS. 8A-C, and 9A-B, while explain based on the aluminium oxide waveguide core embodiment, can also be applied to the aluminium nitride embodiment.

A second possible implementation for depositing the aluminium oxide waveguide core 11 such that nano-crystallites are formed is discussed below. The conceptual explanation of the nano-crystallites given in relation to FIGS. 8A-C applies to this implementation as well.

To deposit the waveguide core, an aluminium oxide film may be deposited using reactive magnetron sputtering. An O₂ flow of 2.8 sccm with a deposition rate of 3.74 nm/min and a stage temperature of 760° C. was used to deposit a 786 nm thick Al₂O₃:Er³⁺ layer with a refractive index of 1.739 at 1030 nm, which was measured using variable angle spectroscopic ellipsometry, VASE. Erbium concentration of the layer is approximately known to be 3.9×10²⁰ ions/cm³ using calibrated sputtering powers based on Rutherford backscattering measurements, RBS. Samples were stored in N₂ ambient in between fabrication steps to avoid OH contamination which is a known source of recombination centres in erbium-doped amplifiers. Electron-beam lithography, EBL, was used to pattern negative resist at a dose of 1000 μC/cm² to be used as an etch mask for the definition of spirals, ring resonators and straight waveguides for signal enhancement and background loss characterization. Reactive ion-etching, RIE, was performed to define the waveguides with 25 and 10 sccm of BCl₃ and HBr gas flows respectively at a chamber pressure of 3 mTorr and 25 W RF power. Plasma-enhanced chemical vapour deposition, PECVD, was used to deposit a SiO₂ cladding at a deposition rate of 37 nm/min using 200 and 710 sccm of SiH₄/N₂ and N₂O respectively, with a chamber pressure of 650 mTorr at 300° C. stage temperature and 60 W of power. Chips were diced and annealed at 550° C. in a tube furnace with N₂ ambient. In order to reduce the coupling losses (ac), chip sidewall polishing was performed to reduce scattering losses using a Flex Waveguide Polisher from KrellTech with a variety of polishing pads of varying roughness of 3.0, 1.0 and 0.3 μm wet with demi water.

Using this particular example, an Al₂O₃:Er³⁺ waveguide may be manufactured which demonstrates gain at 1532 nm of 33.5 dB, with 475 mW (26.1 dBm) of on-chip power for a 12.9 cm amplifier.

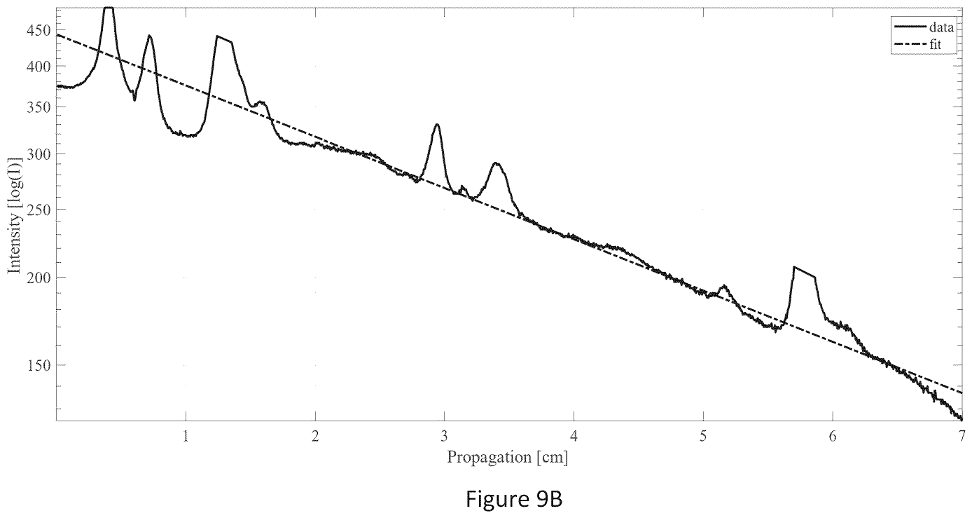

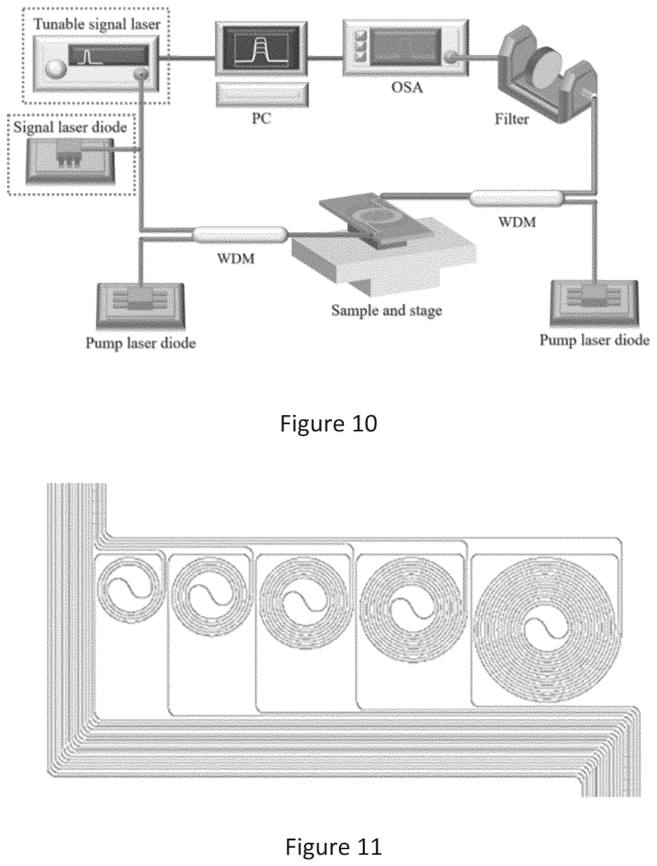

This can be derived, for example, using a set up as shown in FIG. 10, including amplifiers with bidirectional pumping using off-chip WDMs and a filter to cut-off spectra below 1500 nm. In such a set-up, two signal sources may be used for switching from low to high power signal regimes. The resulting signal may be monitored using an optical spectrum analyzer, OSA. Spirals of different lengths (see FIG. 11) were measured for varying pump and signal powers, demonstrating peak on-chip gain per unit length of 3.5 dB/cm at 1532 nm in a 4.9 cm amplifier.

The reactively sputtered Al₂O₃:Er³⁺ waveguide amplifiers has an erbium concentration of 3.9×10²⁰ ions/cm³ and is capable of achieving over 30 dB gain at 1532 nm using bidirectional pumping at 1480 nm, as can be observed relying on the set up shown in FIG. 10. Chip output powers shown here exceed 120 mW, demonstrating the advantages achieved in an optical waveguide core manufactured according to the method of the invention.

The inventive concept generally concerns providing a waveguide core, having a minimum amount of quenching. This can be achieved via a method as described herein.

Quenching may be said to, more or less, be a result of the clustering of rare earth ions. If most ions are part of a cluster, it becomes more likely a photon emitted due to spontaneous emission is emitted in a cluster, meaning it is more likely to interact with other nearby ions in said cluster. Therefore, as an alternative, a method according to the invention can be characterized in that depositing the waveguide core comprises forming nano-crystallites in the waveguide core, wherein a lowest temperature at which a percentage of rare earth ions that is comprised by clusters significantly increases exceeds the given maximum temperature, and that the given maximum temperature is about 400 degrees Celsius or higher.

Larger clusters mean that a photon emitted by an ion due to spontaneous emission is more likely to interact with other nearby ions, if only because in larger clusters, there are more nearby ions. Therefore, as an alternative, a method according to the invention can be characterized in that depositing the waveguide core comprises forming nano-crystallites in the waveguide core, that the lowest temperature at which an average size of clusters of ions significantly increases, exceeds the maximum temperature and that the given maximum temperature is about 400 degrees Celsius or higher.

In the art of crystallography, clusters are sometimes described based on the number of ions included therein, e.g. a monomer refers to a lone ion in an otherwise at least locally uniform host material. A dimer refers to a cluster of two, and a trimer refers to a cluster of three. Having no clusters of rare earth ions can therefore be positively formulated as that the rare earth ions that are present, are monomers. Therefore, as an alternative, a method according to the invention can be characterized in that depositing the waveguide core comprises forming nano-crystallites in the waveguide core, that the lowest temperature at which a number of monomer ions significantly decreases exceeds the given maximum temperature, and that the given maximum temperature is about 400 degrees Celsius or higher.

In the above, the present invention has been explained using detailed embodiments thereof. However, it should be apparent to the skilled person that various modifications are possible to these embodiments without deviating from the scope of the present invention, which is defined by the appended claims and their equivalents.

1. A method for manufacturing an optical waveguide, the method comprising:
providing a substrate;
depositing an aluminium oxide waveguide core layer doped with ions of a rare earth metal onto the substrate; and
arranging a cladding layer on the deposited waveguide core;
wherein depositing the aluminium oxide waveguide core comprises forming nano-crystallites in the aluminium oxide waveguide core that are between about 1 nanometre and about 30 nanometre in size and that form at least 50% by weight of the aluminium oxide waveguide core and wherein the cladding layer is a high-temperature cladding layer.

2. The method according to claim 1, wherein said arranging the cladding layer comprises at least one processing step during which the deposited waveguide core is subjected to a given maximum temperature, wherein the given maximum temperature is about 400 degrees Celsius or higher.

3. The method according to claim 2, wherein said depositing the aluminium oxide waveguide core is such that a quenching percentage of the deposited waveguide core does not significantly increase as a result of the subsequent arranging of the cladding layer.

4. The method according to claim 2, wherein a lowest temperature at which a quenching percentage of the deposited waveguide core would significantly increase, exceeds the given maximum temperature.

5. The method according to claim 3, wherein an increase in the quenching percentage is significant when the increase is about 20% or more.

6. The method according to claim 2, wherein the given maximum temperature lies in a range between about 400 and about 1400 degrees Celsius.

7. The method according to claim 2, wherein arranging the cladding layer comprises depositing the cladding layer on the deposited waveguide core, and wherein said at least one processing step comprises annealing the combination of the substrate, deposited waveguide core, and deposited cladding layer at said given maximum temperature.

8. The method according to claim 7, wherein the quenching percentage of the aluminium oxide waveguide core after said deposition of the cladding layer and before said annealing is between about 5% and about 35%.

9. The method according to claim 7, wherein the quenching percentage of the waveguide core after said annealing is between about 0% and about 35%.

10. The method according to claim 2, wherein said at least one processing step comprises depositing the cladding layer on the aluminium oxide waveguide core at said given maximum temperature.

11. The method according to claim 10, wherein the quenching percentage of the aluminium oxide waveguide core after said deposition of the cladding layer is between about 0% and about 35%.

12. The method according to claim 1, wherein the rare earth metal is a lanthanide.

13. The method according to claim 1, wherein the aluminium oxide is stoichiometric, and/or wherein the waveguide core comprises AlₓO_{y}, wherein 1.5<x<2.5 and 2.5<y<3.5.

14. The method according to claim 1, wherein the waveguide core is grown using any one of reactive sputter deposition, atomic layer deposition, evaporation, or pulsed laser deposition.

15. The method according to claim 1, wherein the cladding layer comprises a TEOS layer, a Silicon oxynitride layer, or a polymer layer.

16. The method according to claim 1, wherein the cladding layer is arranged using any one of plasma enhanced vapor deposition, low pressure chemical vapor deposition, evaporation, sputtering, or atomic layer deposition.

17. The method according to claim 1, wherein the substrate comprises a silicon substrate, a silicon thermal oxide substrate, or a quartz substrate.

18. The method according to claim 1, wherein the optical waveguide is a slab waveguide or a channel waveguide.

19. The method according to claim 1, further including, between depositing the aluminium oxide waveguide core and arranging the cladding layer, reducing surface roughness of the aluminium oxide waveguide core.

20. The method according to claim 1, further comprising defining a shape and/or size of the aluminium oxide waveguide core using, for example, at least one of lithography and etching, before ranging arranging the cladding layer.

21. The method according to claim 1, comprising:
at a deposition rate for aluminium oxide, depositing aluminium oxide layers doped with rare earth ions at varying substrate temperatures and/or at varying substrate bias voltages on respective substrates;
for each deposited aluminium oxide layer, measuring its quenching percentage;
selecting, as optimal settings, said deposition rate and the substrate temperature and substrate bias voltage with which the aluminium oxide layer was manufactured that had the lowest quenching percentage; and
using the optimal settings when depositing the aluminium oxide waveguide core for manufacturing the optical waveguide.

22. An optical waveguide, comprising:
a substrate;
an aluminium oxide waveguide core doped with ions of a rare earth metal, arranged on the substrate; and
a cladding layer arranged on the waveguide core;
wherein the aluminium oxide waveguide core comprises nano-crystallites, wherein a quenching percentage of the optical waveguide is 5% or less, and wherein the cladding layer comprises a high-temperature cladding layer;
wherein the nano-crystallites are between about 1 nanometre and about 30 nanometre in size, and wherein the nano-crystallites form at least 50% by weight of the aluminium oxide waveguide core.

23. The optical waveguide according to claim 22, wherein the high-temperature cladding layer is a cladding layer of which the process for arranging it comprised at least one processing step during which said aluminium oxide waveguide core was subjected to a temperature equal to or greater than 400 degrees Celsius.

24. The optical waveguide according to claim 22, wherein the high-temperature cladding layer comprises at least one a TEOS layer or a Silicon oxynitride layer.

25. The optical waveguide according to claim 22, wherein the waveguide is a slab waveguide or a channel waveguide.

26. (canceled)
